(19) United States
(12) Patent Application Publication
(10) Pub. No.: US 2011/0100440 A1
(43) Pub. Date: May 5, 2011

(54) Optical Rectification Device and Method of Making Same

(75) Inventors: Howard K. Schmidt, Cypress, TX (US); Juan Duque, Los Alamos, NM (US)

(73) Assignee: WILLIAM MARSH RICE UNIVERSITY, Houston, TX (US)

(21) Appl. No.: 12/673,703

(22) PCT Filed: Aug. 14, 2008
(86) PCT No.: PCT/US08/73175

§ 371 Date: Jan. 12, 2011

Related U.S. Application Data
(60) Provisional application No. 60/955,816, filed on Aug. 14, 2007.

(51) Int. Cl. H01L 31/06

(52) U.S. Cl. 136/255

(57) ABSTRACT

A general approach is provided for producing devices that absorb optical photons (visible to near IR) and performs charge separation with a useful voltage between holes and electrons. These holes and electrons may be collected in electrodes for performing useful work outside the device. The described technology is generally based upon rectification of plasmons (collective electric excitations) generated by absorbing light with tuned metallic antennas. According to some embodiments, the present invention provides a spatial array of nanoscale conductors forming an optical rectenna that responds to an incident light source and generates a current offset that may be rectified by a rectification-inducing material. The present inventors foresee an extensive use of these optical rectennas as photovoltaic devices, as well as a wide interest in diverse fundamental research and applied technologies.

### CROSS-REFERENCE TO RELATED APPLICATION

This application claims priority to and benefit of U.S. Provisional Application Ser. No. 60/955,816, filed on Aug. 14, 2007, entitled: “Optical Rectification Device and Method of Making Same”, by inventors Schmidt, et al. [Attorney Docket No. 11321-P160V1], hereby incorporated herein by reference.

### GOVERNMENT SPONSORSHIP

Not applicable.

### FIELD OF THE INVENTION

The present inventions relates to photovoltaic devices based on optical rectification devices, and their application for photovoltaics.

### BACKGROUND OF INVENTION

Due to rapidly rising fossil fuel costs, energy security issues and solar energy harvesting technologies have become increasingly important due to concurrent concerns with increasing fossil fuel costs, energy security and anthropogenic global warming. Renewable energy sources are a topic of high interest. Solar energy is the most abundant renewable source of energy, with an estimated flux of 165,000 terawatts (TW) hitting the earth continuously. Effective conversion (only 0.1 percent) of the incident solar energy into electricity can solve a major part of humanity's energy problems. Photovoltaic (PV) technologies are one the most promising approaches to capture sunlight and generate electricity. Most photovoltaic devices are based on exploitation of the absorbing properties of a band gap between adjacent different semiconductor materials. However, there remains a need for alternate approaches to photovoltaic devices.

### BRIEF DESCRIPTION OF INVENTION

A general approach is provided for producing devices that absorb optical photons (visible to near IR) and performs charge separation with a useful voltage between holes and electrons. These holes and electrons may be collected in electrodes for performing useful work outside the device. The described technology is generally based upon rectification of plasmons (collective electric excitations) generated by absorbing light with tuned metallic antennas.

According to some embodiments, the present invention provides a spatial array of nanoscale conductors forming an optical rectenna that responds to an incident light source and generates a current offset that may be rectified by a rectification-inducing material. The present inventors foresee an extensive use of these optical rectennas as photovoltaic devices, as well as a wide interest in diverse fundamental research and applied technologies.

Thus, according to some embodiments, an optical rectification device, comprises a plurality of optically responsive members, each optically responsive member comprising an optical antenna; and a diode comprising a layer disposed over the nanostructure, the layer comprising a rectification-inducing material.

The rectification-inducing material may comprise first ionic moieties. The first ionic moieties are arranged in a surface region of the layer and a plurality of second ionic moieties may be associated with the first ionic moieties in a bilayer comprising the surface region and the second ionic moieties. The first and second ionic moieties may be arranged so as to form a plurality of dipoles. The second ionic moieties may be derived from a transparent nongaseous conductive medium. The diodes may be disposed between the transparent nongaseous conductive medium and the antennas. The first ionic moieties may be surfactant head groups. The first ionic moieties may be ionized species of a ceramic having an isolectric point.

The rectification-inducing material may comprise a semiconductor adapted for forming Schottky barriers with said optical antennas.

According to some embodiments, an optical rectification device comprises a plurality of optically absorbing nanoscale conductors; a transparent nongaseous conductive medium; and a rectification-inducing material disposed so as to mediate electrical communication between the optically absorbing nanoscale conductors and the transparent nongaseous conductive medium.

The rectification-inducing material may be arranged in a plurality of layers each disposed over one of the optically absorbing nanoscale conductors. The rectification-inducing material may comprise a surfactant. The rectification-inducing material may comprise a ceramic having an isoelectic point. The rectification-inducing material may comprise semiconductor adapted for forming Schottky barriers with said nanoscale conductors. When the rectification-inducing material comprises a semiconductor, the transparent nongaseous conductive medium may comprise a bulk portion of the semiconductor.

The rectification-inducing material may comprise first ionic moieties. The optical rectification device according to claim 16, wherein the first ionic moieties may be arranged in a surface region of the layer. The transparent nongaseous conducive medium may comprise a plurality of second ionic moieties associated with the first ionic moieties in a bilayer comprising the surface region and the second ionic moieties. The first and second ionic moieties may be arranged so as to form a plurality of dipoles.

According to some embodiments, an optical rectification device is made by a method comprising providing a plurality of optical antennas; adding to the plurality a mixture comprising a transparent nongaseous conductive medium and a surfactant.

According to some embodiments, an optical rectification device is made by a method comprising providing a plurality of optical antennas; coating the optical antennas with a ceramic so as to form a treated array; and adding to the treated array a transparent nongaseous conductive medium.

According to some embodiments, An optical rectification device is made by a method comprising providing an array of metallic optical antennas; and adding to the array a transparent nongaseous semicoconductive medium that forms a Schottky bather with said metallic optical antennas. It will be understood that the above-described embodiments may be practiced singly or in combination.

Further, each number written will be understood as if modified by the term “about” preceding the number.

### BRIEF DESCRIPTION OF DRAWINGS

The foregoing summary as well as the following detailed description of the preferred embodiment of the invention will be better understood when read in conjunction with the appended drawings. It should be understood, however, that the invention is not limited to the precise arrangements and instrumentalities shown herein. The components in the drawings are not necessarily to scale, emphasis instead being placed upon clearly illustrating the principles of the present invention. Moreover, in the drawings, like reference numerals designate corresponding parts throughout the several views.

The invention may take physical form in certain parts and arrangement of parts. For a more complete understanding of the present invention, and the advantages thereof, reference is now made to the following descriptions taken in conjunction with the accompanying drawings, in which:

FIG. 1 depicts a metallic nanowire array with a rectifying self-assembled monolayer (SAM) junction;

FIG. 2 shows TEM representative of CNTs used in photocurrent experiments to obtain the data shown in FIG. 3; scale bar is 0.5 micron;

FIG. 3 shows experimentally observed photocurrent response of CNT cathode to photon flux with various electrolytes. Adding SDBS clearly results in rectified photocurrent;

FIG. 4 shows a calculated nanowire voltage response upon photoabsorption as a function of antenna length and photon energy;

FIG. 5 shows a calculated potential well created by a charged nanotube within an anionic surfactant micelle;

FIG. 6 shows experimentally observed SEM images of fCNTs with and without Au;

FIG. 7 shows experimentally observed photocurrent current as function of wavelength for fCNTs with (line 20), without (line 10) Au and not CNT as reference (line 30); and

FIG. 8 shows experimentally observed current generation as function of time for fCNTs-Au exposed to 400 nm wavelength light, after cyclically turning light on and off, where the insert is the discharge at each cycle.

### DETAILED DESCRIPTION

A general approach is provided for producing devices that absorb optical photons (visible to near IR) and performs charge separation with a useful voltage between holes and electrons. These holes and electrons may be collected in electrodes for performing useful work outside the device. The described technology is generally based upon rectification of plasmons (collective electric excitations) generated by absorbing light with tuned metallic antennas.

The present optical rectification device employs optically absorbing nanoscale conductors. The optically absorbing nanoscale conductors may be optical antennas. According to some embodiments, the antennas are nanowires. According to some embodiments, the antennas may be fabricated primarily with carbon nanotubes (CNTs). Carbon nanotubes may be coated with metal. It will be understood herein that nanowires are exemplary of optically absorbing nanoscale conductors. The optically absorbing nanoscale conductors may be arranged as an array. The nanoscale conductors may be formed as protrusions from a solid. The protrusions may be coated, for example with metal. Thus, the nanoscale conductors may be formed of a based material coated with metal.

The present inventors contemplate that these structures will generate transient voltages on the order of one volt when irradiated with light in the visible range. With tip radii in the nanometer range, this will generate electric fields sufficient for field emission. The device uses a rectification-inducing material to generate a rectifying barrier. The switching speed of the rectifier permits the device permits the generation of voltage when the device is irradiated with light in the visible range. The device may include electrodes adapted for transmission of electricity outside the device via the electrodes.

According to some embodiments, the rectification-inducing material contains ionized molecules. According to some embodiments, the ionized molecules are surfactant molecules. Thus the rectification-inducing material may be a surfactant. The ionized molecules may be arranged into a monolayer. The monolayer may have self-assembled. Thus the monolayer may be self-assembled monolayer. The ionized molecules may include ionized moieties. When the ionized molecule is a surfactant, the ionized moiety is the surfactant head group. The ionized moieties may be arranged outwardly of the antennas. An ionized moiety exemplary of a first ionic moiety may pair with a nearby counter ion exemplary of a second ionic moiety so as to form a dipole. The first and second ionic moieties form an ordered polarized bilayer that provides rectification.

The optical rectification device may include a transparent nongaseous conductive medium. The transparent nongaseous conductive medium may be an electrolyte. It will be understood that an electrolyte is herein exemplary of a transparent nongaseous conductive medium. The second ionic moiety may be derived from the electrolyte.

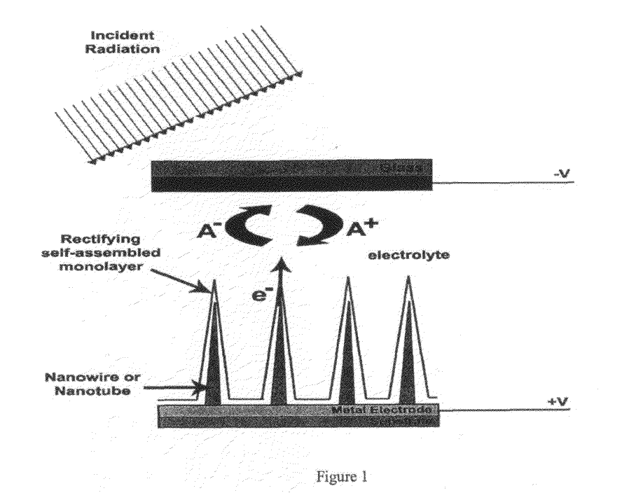

An exemplary device is shown in FIG. 1.

It will be understood that while the nanowires may be depicted herein with a triangular cross-section, such as from associated with a cone shape or a pyramid shape or the like, alternative shapes are contemplated, such a rods, ellipsoids, cones, platelets, and the like, and portions and/or combinations of the shapes described.

According to some embodiments, the diameter of a nanowire is large enough to avoid quantum capacitance and kinetic inductance capable of pushing the antenna resonance of the nanowire down to undesirably low frequencies. For example, the tip diameter may be 10 nm or larger. The present inventors expect that a carbon nanotube, or any metallic nanowire, with a diameter of 10 nm or larger has a group velocity close to the speed of light, and so behave predictably as a dipole antenna, typically at λ/4 or λ/2, even into the optical regime.

According to some embodiments, the tip diameter is small enough to provide a low enough capacitance that increases the frequency response of the diode, a desirable factor for rectenna operation. For example, the tip diameter may be up to 100 nm.

Thus, for example, the present inventors contemplate using nanowires in the 10-100 nm tip diameter range.

The antennas are desirably no farther apart than the average wavelength of light impinging them. Otherwise there may tend to be ‘dead space’ and system efficiency may tend to suffer. According to some embodiments, the antennas are at least 0.25 times the wavelength of light to be converted. Thus, according to some embodiments, the antennas are between 0.25 and 1 times the wavelength of light to be converted.

According to some embodiments, an orderly array of metallic nanowires protrudes vertically from a conductive substrate.

According to some embodiments, the substrate may be provided with an insulating layer all over, except where the nanowires protrude into the electrolyte.

According to some embodiments, the order dipole bilayer is disposed over the tips and sides of the nanowires. Alternatively, the sides of the nanowires may be coated with an insulator.

According to some embodiments, the nanowire antenna is conductive. Exemplary candidates are carbon nanotubes, and gold, silver or copper nanowires. Other materials should work, but might be less efficient at converting light into electricity due to higher resistance at optical frequencies, for example, tungsten or graphitic carbon. According to some embodiments, a conductive material is coated on a template of suitable dimensions to realize the optical antenna. An example is gold coated-carbon nanotubes.

According to some embodiments, simply placing conductive particles on a conductive plane should have a similar effect. Candidate particles could include gold and silver nanoparticles and similar structures, like gold/silica nanoshells. These should be sized/proportioned such that they absorb light at some desired frequency—e.g. in the visible or in the IR.

It will be understood that the devices described herein may also generate photocurrent from localized electronic excited states, e.g. resonant high-energy molecular absorptions.

It will be understood that, when an electrolyte is used, the present device desirably operates in a temperature for which the electrolyte is liquid. For example, an electrolyte used in Example 1 freezes below 0 C and boil over 100 C.

It will be understood that polymeric polyelectrolytes such as poly-phenylsulfonate and Nafion (a sulfonated fluorocarbon polymer) are suitable electrolytes.

It will be understood that the present inventors contemplate alternatives to aqueous electrolytes. Electrochemistry is often performed in acetonitrile and other aprotic polar liquids. These usually have lower dielectric constants than water, and this could increase the voltage swing produced when the nanowires absorb light.

It will be understood that the substrate desirably has good conductivity. For example, when the current density is low, materials that are good conductors and less conductive than the best conductive materials may be used. Thus, carbon, aluminum, doped silicon, etc. may all be used effectively.

Similarly, there are a large number of possible variations for the surface coating of the nanowire to produce a bilayer of ordered dipoles. This layer is desirable for the rectification function that allows collection of current from the optical antennas. For electron emission, the present inventors contemplate a dipole with the negative charge closest to the nanotube. There are many suitable sulfonate surfactants. Similarly organic acids should also serve the purpose, although they might have lower levels of ionization, since they are weaker acids than the sulfonic acids.

We believe that cationic surfactants could generate cations in solution, by extracting electrons from species in solution (the nanowires will have positive voltage swings of magnitude equal to the negative excursions that facilitate electron emission). Thus, we could make a photocell with inverted polarity with ammonium salt surfactants (e.g. CTAB—cetyl trimethyl ammonium bromide).

According to some embodiments, a surfactant that coordinates to the nanowire surface by van der Waals attraction. This works well on carbon nanotubes that have graphene-like surfaces.

Alternatively, on transition metal nanowire surfaces different surface chemistry may be used. For instance alkyl- and aryl-thiols are well known from the SAM (self assembled monolayer) and molecular electronics literatures to form electrically active bonds between the metal surface and the sulfur atom in thiols, organic di-sulfides and the like. These are usually fitted with an organic spacer linkage, e.g. dodecyl groups. The distal end of the organic spacer could be fitted with a polar group (e.g., —CN, —CHO, or similar) or an ionizable group (e.g. —COOH, —SO₃H, or similar) to generate the rectification function. This generally works well with metals that do not easily oxide spontaneously (e.g. gold, platinum, palladium), and to a certain extent with coinage metals like copper and silver.

Similarly, metals that spontaneously generate a surface oxide can be supplied with a polar ligand via coordination chemistry. For example the oxidized surface of aluminum readily coordinates with organic carboxylic acids. This, and similar, interfaces will have a certain dipole moment of their own and may provide rectification. To increase dipole magnitude we can see that the organic species attached to the carboxylic acid (or similar coordinating moiety-like amines, etc.) can be supplied with distal polar or ionizable moieties, just like the sulfides described above.

According to some embodiments, an ordered dipole bilayer is formed by the interaction of a ceramic having an isolectronic point with an electrolyte solution. The present inventors note that many materials generate a spontaneous surface charge when immersed in an electrolyte. This is the basis for colloid chemistry. The sign and density of charge on such surfaces is a function of pH in the host solution. The pH where the charge is zero is called the isoelectronic point, and this is generally a material-specific value. It is apparent from the above table that titanium dioxide would in particular provide a versatile interface material since its isoelectric point is close to neutral pH.

In particular as noted at Wikipedia, “The isoelectric points (IEP) of metal oxide ceramics are used extensively in material science in various aqueous processing steps (synthesis, modification, etc.). For these surfaces, present as colloids or larger particles in aqueous solution, the surface is generally assumed to be covered with surface hydroxyl species, M-OH (where M is a metal such as Al, Si, etc.). At pH values above the IEP, the predominate surface species is M-O⁻, while at pH values below the IEP, M-OH⁺ species predominate.” Further noted at the same site: “Mixed oxides may exhibit isoelectric point values that are intermediate to those of the corresponding pure oxides.” Values reported at the same site are listed below:

| Material | Isolectronic point |
|---|---|
| antimony oxide SbO₃ | <1 |
| Tungsten oxide WO₃ | <1 |
| vanadium oxide (vanadia) V₂O₅ | 1-2 |
| silicon oxide (silica) SiO₂ | 1-3 |
| silicon carbide (alpha) SiC | 2-3.5 |
| tin oxide SnO₂ | 4-5.5 |
| zirconium oxide (zirconia) ZrO₂ | 4-7 |
| manganese oxide MnO₂ | 4-5 |
| Titanium oxide (titania) TiO₂ | 4-6 |
| iron (IV) oxide Fe₃O₄ | 6.5 |
| gamma iron (III) oxide Fe₂O₃ | 7 |
| cerium oxide (ceria) CeO₂ | 7 |
| chromium oxide (chromia) Cr₂O₃ | 7 |
| gamma aluminum oxide (gamma alumina) | 7-8 |
| Al₂O₃ | |
| Thallium oxide Tl₂O | 8 |
| alpha iron (III) oxide Fe₂O₃ | 8-9 |
| alpha aluminum oxide (alpha alumina) Al₂O₃ | 8-9 |
| yttrium oxide (yttria) Y₂O₃ | 9 |
| copper oxide CuO | 9.5 |
| zinc oxide ZnO | 9-10 |
| lanthanum oxide La₂O₃ | 10 |
| nickel oxide NiO | 10-11 |
| magnesium oxide (magnesia) MgO | 12-13 |

Thus, the present inventors contemplate coating a conductive nanowire with a very thin layer of polarizing inorganic material to generate the ordered dipole bilayer to realize the rectification function in this class of devices. The degree of ionization, and thus rectification factor, could be controlled by setting the pH of the electrolyte to specific values.

It will be understood that though it is known in the art that the exact value of the isolectronic point report as reported by different researchers may vary within a range, it is within the skill of one of ordinary skill in the art to determine empirically the effective isolectronic point of a material used in the present device.

According to some embodiments, solid-state versions of the present device are contemplated. For instance gold, exemplary of a metal, makes a Schottky barrier diode with both p- and n-silicon, exemplary of a semiconductor. Suitable conductive nanowires (photon absorbers) are embedded into a suitable semiconductor matrix, then hot electrons should jump the junction barrier and be free to collect in the semiconductor. The doped silicon layer might be fabricated by depositing via CVD or plasma enhance CVD on top of the nanowire array. It is noted that anatase (TiO2) is a nice n-type semiconductor with a 3 eV bandgap or so. This is expected to make a Schottky barrier diode with gold nanowires or carbon nanotubes. It is known that anatase in the form of 20 nm diameter nanoparticles is used as an electron conductor in dye sensitized solar cells A coating of anatase may be generated from such powders atop the nanowire array to generate the rectifying junctions and collect electrons from a contact applied atop the silicon or anatase (for example). It will be understood that the layer of semiconductor adjacent the metal acts as the rectification-inducing material.

The present inventors contemplate a ‘substrateless’ variation on this device. In other work, we have developed methods for placing or growing metal particles on the ends of nanotubes. A good electrochemical electrode material may be placed at only one end of the nanowire antenna structure. Thus, the nanowire may emit electrons into solution, while the metal particle may serve as the positive electrode in a single-nanowire electrochemical device. These may be employed to use sunlight to split water or drive other useful electrochemical reactions in situ with the nanowires suspended in the reactor medium.

The present device does not depend on any particular method for fabricating the antenna array. The example given is a random pile of nanowires of which a small fraction protrude to form active antennas. Vertical arrays of nanowires formed by CVD (chemical vapor deposition) techniques may alternatively be used. An example of these are carbon nanotube forests grown by CVD. These are known and have been grown, for example, at ORNL and Boston College.

Metallic nanowires can be generated without templates (e.g. anodic alumina or ion track membranes). Further, they can be generated in solution using surfactants to promote anisotropic growth. Similarly, one can use surfactants and electrical tricks to promote anisotropic growth of cones, pyramids and rods from a conductive substrate using electrochemical deposition.

When the sides of the nanowires may be coated with an insulator, the present inventors contemplate gainfully using nanowires produced by electroplating within high aspect ratio pores. Two suitable methods for generating suitable pores are ion track membranes and anodic alumina.

It will be understood that various known methods of making nanowires may be used. Known methods are described for example in Y. Xia, et al. Adv. Mater. 15, 353 (2003).

It will be understood that the antenna structure may be assembled from a number of smaller entities. For example, small diameter single wall carbon nanotubes (SWNT) can readily form bundles; these are often 10 nm to 100 nm in diameter. Since these may have a substantial fraction of metallic SWNT, the aggregate may behave like a metallic antenna if the dimensions are appropriate (a few hundred nm in length for visible radiation). The present inventors note that such SWNT (and small diameter MWCNT) arrays can be ‘formed’ into macrostructures when immersed or contacted with liquids with high surface tension. Typically, ridges, mesas and spikes result from the surface tension of liquid droplets as they evaporate. Often the vertical SWNT arrays processed at CNL are at least 10 microns in height. The present inventors contemplate fabricating very short arrays (about 250 nm high) to test their performance as photocathodes. The present inventors expect that when wetted with polar liquids, these short carpets will collapse to form a semi-regular array of spikes. The present inventors expect these will behave nicely as optical antennas. They may be coated with gold or similar processes to improve performance, as similarly noted herein.

An exemplary primary application of the present devices is generation of electricity from sunlight. Given the compound threat of anthropogenic global warming and decreasing access to dwindling petroleum/gas resources, there is increasing interest in environmentally friendly domestic energy sources. Solar energy is one promising solution. Solar is the most abundant renewable energy source, with an estimated flux of 12,000 terawatts (TW; 10¹² watts) impinging the earth continuously. Global power consumption now stands at about 13 TW. Thus, if even 0.1% of the sunlight were converted into electricity, a large part of our energy problems could be solved. Photovoltaic (PV) technologies are a particularly promising approach to capture sunlight and generate electricity. Another useful application of the described device is as a photodetector, disposed as a single detector element or as an array for imaging. A particularly valuable application would be for detecting and imaging in the infrared regime.

The present device allows a new class of nanowire based PV devices with several potential benefits. In particular, there is a potential for much higher conversion efficiency. In particular, the physics of the device suggests a theoretical efficiency of 95%. Further, simple device structure, non-vacuum operation and utilization of standard large area manufacturing equipment will facilitate scale-up and reduce production costs. Still further, the present device avoids UV-sensitive materials therefore the present inventors expect the present device to tend to provide long operating life and high reliability.

The following examples are included to demonstrate particular embodiments of the present invention. It should be appreciated by those of skill in the art that the methods disclosed in the examples that follow merely represent exemplary embodiments of the present invention. However, those of skill in the art should, in light of the present disclosure, appreciate that many changes can be made in the specific embodiments described and still obtain a like or similar result without departing from the spirit and scope of the present invention.

### EXAMPLES

### Example 1

This example illustrates rectification using a surfactant.

The present inventors obtained small DC photocurrents from carbon nanotube electrodes in aqueous electrolytes, demonstrating conversion of light to electricity. The demonstration device described in this example was produced by coating carbon tape (conductive adhesive) with carbon nanotubes; this was affixed to a conductive substrate which served as an electrode. This was immersed in a aqueous electrolyte solution of SDBS (sodium dodecylbenzene sulfonate) and Fe(EDTA)₂. SDBS is a common detergent. A gold wire or similar was immersed into the electrolyte, but not directly in contact with the carbon tape or its supporting electrode. Upon irradiation with light, electrons were emitted from the nanotubes into the solution. Electrons were carried to the gold wire, which charged negative; the substrate in contact with the nanotubes charges positive.

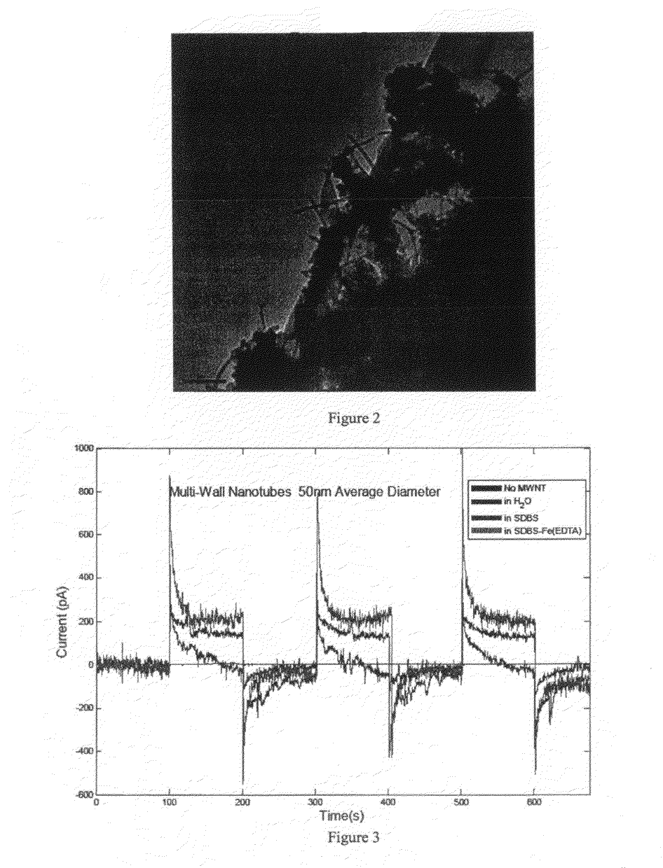

In particular, the present inventors fabricated a photocathode by sticking MWCNTs from Mitsui onto a 2 mm diameter patch of conductive carbon tape, which was affixed to an ITO coated glass substrate. A PDMS (poly-dimethylsiloxane) cylinder (PDMS is optically transparent, and allows illumination of the sample) was glued around the cathode to hold electrolyte fluid, and a gold wire was used as the anode. Current was measured with a Kiethly nanometer, and logged in real time by a computer under LabView control. Illumination was provided by a 35 watt quartz tungsten halogen lamp fitted with a glass fiber optic delivery path. A TEM representative of lumped MWCNTs used in the test appears in FIG. 2. Photocurrents recorded with deionized water, 1 wt % SDBS solution and 1 wt % SDBS solution doped with 100 μM Fe(EDTA)₂ (electron carrier) are shown in FIG. 3. The steps coincide perfectly with when we turned the lamp on in 100 second bursts. A uncoated carbon tape with SDBS+Fe(EDTA)₂ electrolyte (flat line at zero) served as negative control.

It is apparent that even in DI water, the CNTs have some photo-response. We attribute the positive and negative spikes to charge and discharge of the CNT mass. These results are comparative, as are those for the uncoated carbon tape.

Upon addition of the SDBS, which should coat the CNT surfaces with a dipole SAM similar to that described above, we see that the positive spike turns into an extended step and the negative spike is greatly attenuated. This clearly shows that a rectified photocurrent is generated in the system. Upon addition of Fe(EDTA)₂, we observe that the photocurrent increases slightly, as one would expect with improve electron transport in the electrolyte. The recorded photocurrents are small. However, as seen from the TEM, and a vanishingly small fraction of the CNTs acting as optical antennas protrude from the mass. Thus, the present inventors expect largers currents from more orderly arrays of CNTs.

The present inventors believe the SDBS forms an ordered monolayer on carbon nanotube surfaces with the hydrocarbon tails in contact with the nanotube surface. The contact is believed to be van der Waals contact. The hydrocarbon tails are hydrophobic. The polar, ionized sulfonate head groups is oriented away from the nanotube surface and has a negative charge in water. It's counter ion, sodium, resides nearby in solution. This ion pair forms an ordered dipole bilayer that provides rectification.

### Example 2

### A Prophetic Example

This example illustrates generation of a voltage by a nanoscale antenna.

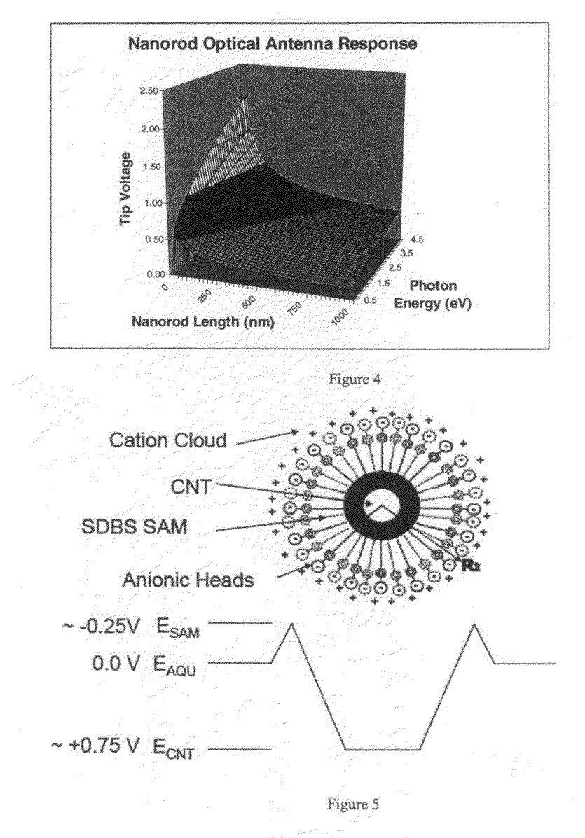

The present inventors model the voltage generated at the tip of a nanowire antenna. The present inventors assume that initially the amount of energy stored in the polarized wire is equal to the energy in the incoming photon hv. It is known that the polarization of a conducting wire in an axial electric field is P=γ↑E|L³/Λ, where the geometrical factor Λ=[24 ln(4L/d)−7] and E is the applied field; L and d are the length and diameter of the rod, respectively. The energy stored is given by the product of electric field and the polarization: D=P E, while the apparent voltage (relative to immediate surroundings) at the tip will be E L/2. Equating the D is with hv, it is possible to compute the field that would have generated such a dipole, and thus the impressed voltage at the tip of the wire. FIG. 4 shows the results. For example, the present inventors predict that a 10 nm×150 nm antenna (λ/4 resonant with green light) will generate a useable signal around one volt.

### Example 3

### Another Prophetic Example

This example illustrates rectification by an dipole bilayer.

The present inventors model the potential well created by a charged nanotube with a surfactant micelle. The present inventors reasonably assume a surfactant structure as shown in FIG. 5 along with a surfactant anionic charge density of 0.1 C/m² and a nominal surfactant dipole moment of 20 Debye. It is possible to compute the size of the offset from the bath using Gauss's law to determine the radial electric field at various radii based upon the surface area of the cylindrical surface (or hemi-spherical at the ends) and the enclosed charge.

From this, it is possible to see that the region between the ionic component layers has a strong electric field. Upon integrating this field, it is possible determine the size of the voltage offset (the depth of the potential well) caused by the ordered dipole SAM. Results were obtained also for cylindrical and spherical symmetry, corresponding to the sides and ends of the nanotube, respectively. These results showed the variation of the potential with the nanotube diameter, for different nanotubes of varying diameters. The smaller potential for spherical geometry, as compared to that for cylindrical geometry, is due to the 1/r² field gradient as opposed to the 1/r field gradient along the tube sides.

The additional gradient between the tube surface and the anionic shell is computed assuming a nanotube excited state aligns with the top of the surfactant potential well. This allows electron emission from the excited state and results in a positively charged nanotube in solution. The resulting potential well that is predicted is shown in FIG. 5. Note that the shape of the Fermi level results in a barrier to both electron and hole flow between the nanotube and the electrolyte. Thus, the surfactant SAM will operate as a rectifier when electrons are excited over the barrier height by photo excitation.

### Example 4

The present inventors have tested ‘flipped’ SWNT arrays fabricated in CNL (Carbon Nanotube Laboratory—Rice University). These have similar operating characteristics to the multiwall nanotubes described in Example 1. The present inventors think that bundles of SWNT are the operative elements in the device of the present example. Resonant absorptions that generate electronically excited states in the SWNT may also generate a portion of the observed photocurrent.

SWNT carpets were grown onto Si surfaces. The carpets were peeled off the Si surface onto a conductive substrate (ITO or Cu puck) by an adhesive layer, deposited on gold or a patch of conductive carbon tape. The carpets were peeled off the original substrate to obtain individual SWNT and/or small bundles of SWNT protruding from the surface.

For photocathode preparation, PDMS was used as the reservoir, and the electrolyte solution consisted of 1 w % SDBS solution doped with 100 μM Fe-(EDTA). The current was recorded with nanoammeter and ITO was used as a counter electrode.

At a constant light intensity, using a microscope lamp, the carpet system displays the same step behavior as with MWNT when exposing the system to incident light FIG. 5.a. If the light intensity is changed (high, medium and low), the photocurrent generated changes proportionally to the intensity of the light (FIG. 5.b). A negative control is shown in FIG. 5.c, in which no current was generated in the absence of the carpet.

Changing the light source for a Xenon lamp, (450 W) we obtained an enhancement of the photocurrent by 10× fold in contrast to previous results with the microscope lamp. By changing the intensity of the light, we also observed changes in the generated photocurrent.

Using all the wavelengths (white light) from the xenon lamp and just changing the intensity from maximum, medium, and low, the photocurrent exhibits distinctive step behavior. This is in contrast to almost no response when the monochromator was used.

To qualitatively establish the relation between wavelength and the photo response of the system, 450 nm long and a 850 nm short pass filters were mounted before the carpet sample, and illuminated with white light from the xenon lamp (monochromator bypassed).

When both filters were mounted, the photocurrent generated was about 0.7 pA. Removing the 850 nm short pass filter (leaving the 450 nm long-pass filter in place) gave a current of 3.5 pA, while using only the 850 nm filter gave 0.85 pA of current Without the filter, 4.2 pA was obtained. These results indicate that the photocurrent response is coming mostly from wavelengths longer than 850 nm (near infrared).

We scanned the photocurrent generation of MWNT and carpets as a function of wavelength from 200 to 850 nm using a Perkin Elmer fluorescence spectrometer equipped with the 150 W xenon lamp.

The scan revealed a maximum intensity peak at 310 nm with a small peak at 600 nm. We suspect that this peak comes from the π-plasmon resonance of the MWNT. This plasmon feature is usually observed between 5 and 6 eV in vacuum, corresponding to 248 nm to 206 nm. If this peak does arise from the π-plasmon, it has a substantial red-shift; this might be caused by the high dielectric constant of the medium. It is believe that this plasmon resonance is illustrative generally of a plasmon resonance associated with the present nanoscale conductors operating as optical antenna.

Turning the light on and off while measuring the photocurrent response of the system gave very interesting results. By illuminating the sample with white light (bypassing monochromator), we observed some current generation (˜1.3 nA). However, if the sample was irradiated with light at only 310 nm, a 2× fold increment of the generated current was observed (˜3 nA). We speculate that the longer wavelength stimulate a photoconductive process that shorts some of the photocurrent generated at 310 nm. It is important to note that the step increments were always constant for white light as well as for 310 nm. At wavelengths where no current response was recorded in the wavelength scan (500 nm shown), no appreciable current generation was obtained. This holds true for 600 nm where a small peak was observed in the wavelength scan.

In order to corroborate that the tubes are the ones absorbing at 310 nm, we used SDS instead of SDBS, since SDBS has strong absorption below 300 nm. Similar behavior was observed with SDS surfactant.

This example illustrates the following conclusions. A novel photovoltaic device was demonstrated with charge separation and current rectification provided by a self-assembled monolayer of polar molecules. SDBS and SDS monolayers behave as rectifying diodes. Photocurrent generated was linearly dependent on light power. Wavelength dependence to current generation was obtained between 200 and 850 nm; maximum current generation was observed at 310 nm. Pi-plasmon absorption may generate a significant fraction of the observed photocurrent. Photocurrents generated in the Near IR using MWCNT electrodes appear to be due to optical antenna effects.

### Example 5

This example illustrates current generation using nanoplatelets.

Photocurrent generation using graphite nanoplatelets (highly exfoliated natural graphite) on conductive carbon tape were studied with similar results as previously discussed in the above examples, but the photocurrent generated was very close at 310 nm or at white light indicating that the current generated was pronominally from 310 nm wavelength.

### Example 6

This example illustrates generation of current using a surfactant and an array of metal coated nanotubes. Furthermore, this example illustrates that the current generated has wavelength dependence that can be adjusted with deposited metal.

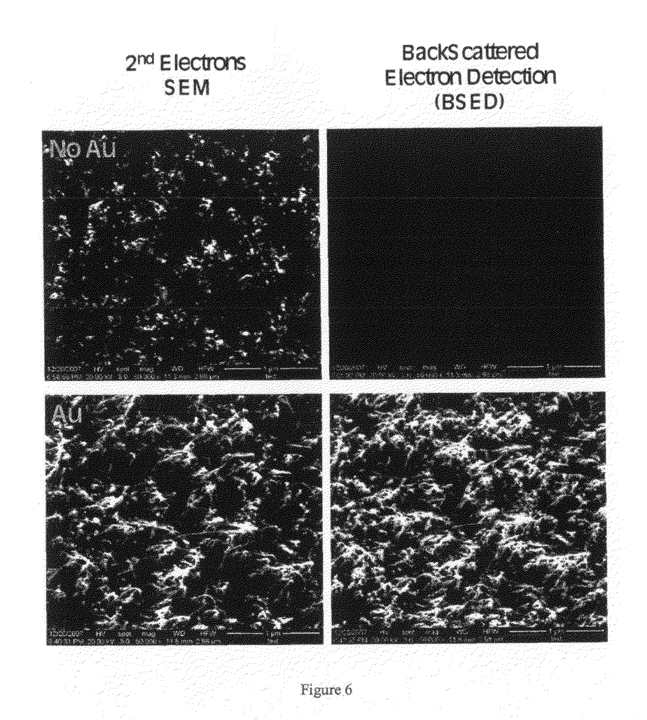

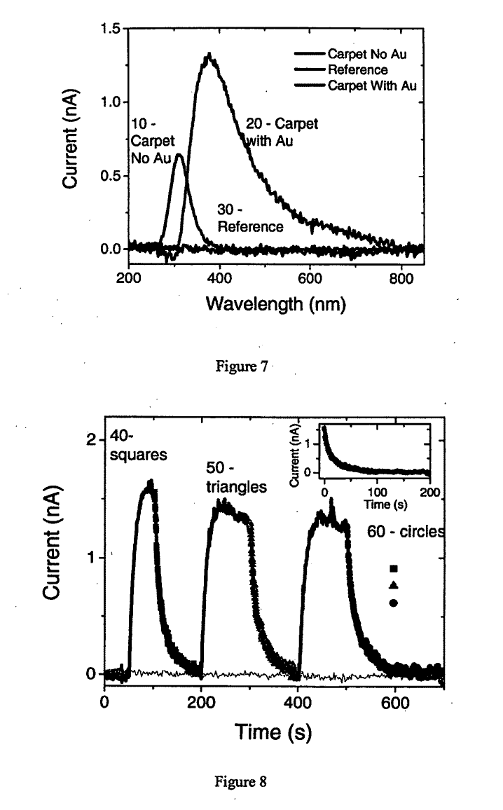

In an attempt to obtain a more efficient photocathode cell that has broadened absorbance in the visible region, we evaporated roughly 10 nm of Au onto fCNTs. Very strong absorption in the visible region is well known for Au, and it is known that the size and shape of the Au nanoparticles can be deduce from to the absorption spectrum. FIG. 6 shows field emission scanning electron microscope (SEM) images of the 2^{nd} scatter and backscattered electron detection (BSED) of flipped carpets with and without Au. These images show bundles of individual SWNTs between 10-50 nm in diameter after the flipping procedure (50,000×). We attribute the current generation to the SWNT bundles. Furthermore, BSED images confirm that Au was deposited onto the CNTs without significantly changing the tube spacing and/or orientation. The electrolyte in this set of experiments was made from a mixture of SDBS and Fe-(EDTA) doped with 12-mercaptododecanoic acid (thiol). Since we expect only partial coverage of the tubes with Au, the thiol serves as the rectifying diode for the fCNT-Au and the SDBS for the uncovered Au CNTs. Photocurrent generation as a function of wavelength with fCNTs after Au deposition displayed a red-shift of the maximum current peak by roughly 100 nm (line 20) in FIG. 7) in contrast to fCNTs without Au (line 10 in FIG. 7). Moreover, fCNTs-Au has a more intense and broader current profile than fCNT without Au, indicating that the photoabsorption can be adjusted by changing the kind of metal coverage and/or thickness. Photocurrent generation was also measured by cycling the light on and off (400 nm wavelength) as function of time (FIG. 8). We observed the same fast response to light as with the other types of CNTs. When the light was turned on or off we observed an exponential increase and decay, respectively, indicating that after exposure to light the CNTs charge and discharge. Moreover, the charge and discharge time constant are constant in every cycle as shown in the insert of FIG. 8 (discharge) with an exponential decay fitting a*exp(−b*t) where a=1.05, and b=0.0404 (Fitting is depicted by solid line in insert FIG. 8). No current was obtained when experiments were performed in the absence of fCNTs as function of wavelength (solid horizontal data line near bottom in FIG. 8).

Although the invention has been described with reference to specific embodiments, these descriptions are not meant to be construed in a limiting sense. Various modifications of the disclosed embodiments, as well as alternative embodiments of the invention will become apparent to persons skilled in the art upon reference to the description of the invention. It should be appreciated by those skilled in the art that the conception and the specific embodiment disclosed may be readily utilized as a basis for modifying or designing other structures for carrying out the same purposes of the present invention. It backscattered electron detection (BSED) of flipped carpets with and without Au. These images show bundles of individual SWNTs between 10-50 nm in diameter after the flipping procedure (50,000×). We attribute the current generation to the SWNT bundles. Furthermore, BSED images confirm that Au was deposited onto the CNTs without significantly changing the tube spacing and/or orientation. The electrolyte in this set of experiments was made from a mixture of SDBS and Fe-(EDTA) doped with 12-mercaptododecanoic acid (thiol). Since we expect only partial coverage of the tubes with Au, the thiol serves as the rectifying diode for the fCNT-Au and the SDBS for the uncovered Au CNTs. Photocurrent generation as a function of wavelength with fCNTs after Au deposition displayed a red-shift of the maximum current peak by roughly 100 nm (line 20) in FIG. 7) in contrast to fCNTs without Au (line 10 in FIG. 7). Moreover, fCNTs-Au has a more intense and broader current profile than fCNT without Au, indicating that the photoabsorption can be adjusted by changing the kind of metal coverage and/or thickness. Photocurrent generation was also measured by cycling the light on and off (400 nm wavelength) as function of time (FIG. 8). We observed the same fast response to light as with the other types of CNTs. When the light was turned on or off we observed an exponential increase and decay, respectively, indicating that after exposure to light the CNTs charge and discharge. Moreover, the charge and discharge time constant are constant in every cycle as shown in the insert of FIG. 8 (discharge) with an exponential decay fitting a*exp(−b*t) where a=1.05, and b=0.0404 (Fitting is depicted by solid line in insert FIG. 8). No current was obtained when experiments were performed in the absence of fCNTs as function of wavelength (solid horizontal data line near bottom in FIG. 8).

Although the invention has been described with reference to specific embodiments, these descriptions are not meant to be construed in a limiting sense. Various modifications of the disclosed embodiments, as well as alternative embodiments of the invention will become apparent to persons skilled in the art upon reference to the description of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

It is therefore, contemplated that the claims will cover any such modifications or embodiments that fall within the true scope of the invention.

What is claimed is:

1. An optical rectification device, comprising:
a plurality of optically responsive members, each optically responsive member comprising:
an optical antenna; and,
a diode comprising a layer disposed over the nanostructure, the layer comprising a rectification-inducing material.

2. The optical rectification device according to claim 1, wherein the rectification-inducing material comprises first ionic moieties.

3. The optical rectification device according to claim 2, wherein the first ionic moieties are arranged in a surface region of the layer and wherein a plurality of second ionic moieties are associated with the first ionic moieties in a bilayer comprising the surface region and the second ionic moieties.

4. The optical rectification according to claim 3, wherein the first and second ionic moieties are arranged so as to form a plurality of dipoles.

5. The optical rectification device according to claim 3, wherein the second ionic moieties are derived from a transparent nongaseous conductive medium.

6. The optical rectification device according to claim 5, wherein the diodes are disposed between the transparent nongaseous conductive medium and the antennas.

7. The optical rectification device according to claim 2, wherein the first ionic moieties are surfactant head groups.

8. The optical rectification device according to claim 2, wherein the first ionic moieties are ionized species of a ceramic having an isolectric point.

9. The optical rectification device according to claim 1, wherein the rectification-inducing material comprises a semiconductor adapted for forming Schottky bathers with said optical antennas.

10. An optical rectification device comprising:
a plurality of optically absorbing nanoscale conductors;
a transparent nongaseous conductive medium; and
a rectification-inducing material disposed so as to mediate electrical communication between the optically absorbing nanoscale conductors and the transparent nongaseous conductive medium.

11. The optical rectification device according to claim 10, wherein the rectification-inducing material is arranged in layers each disposed over one of the optically absorbing nanoscale conductors.

12. The optical rectification device according to claim 10, wherein the rectification-inducing material comprises a surfactant.

13. The optical rectification device according to claim 10, wherein the rectification-inducing material comprises a ceramic having an isoelectic point.

14. The optical rectification device according to claim 10, wherein the rectification-inducing material comprises a layer of a semiconductor adapted for forming Schottky barriers with said nanoscale conductors.

15. The optical rectification device according to claim 10, wherein the transparent nongaseous conductive medium comprises a bulk portion of the semiconductor.

16. The optical rectification device according to claim 10, wherein the rectification-inducing material comprises first ionic moieties.

17. The optical rectification device according to claim 16, wherein the first ionic moieties are arranged in a surface region of the layer.

18. The optical rectification device according to claim 17, wherein the transparent nongaseous conducive medium comprises a plurality of second ionic moieties associated with the first ionic moieties in a bilayer comprising the surface region and the second ionic moieties.

19. The optical rectification according to claim 18, wherein the first and second ionic moieties are arranged so as to form a plurality of dipoles.

20. An optical rectification device made by a method comprising:
providing a plurality of optical antennas;
adding to the plurality a mixture comprising:
a transparent nongaseous conductive medium; and
a surfactant.

21. An optical rectification device made by a method comprising:
providing a plurality of optical antennas;
coating the optical antennas with a ceramic so as to form a treated array; and
adding to the treated array a transparent nongaseous conductive medium.

22. An optical rectification device made by a method comprising:
providing an array of metallic optical antennas; and
adding to the array a transparent nongaseous semicoconductive medium that forms a Schottky barrier with said metallic optical antennas.
